(19) United States
(12) Patent Application Publication
(10) Pub. No.: US 2019/0230784 A1
(43) Pub. Date: Jul. 25, 2019

(54) ELECTRONIC COMPONENT OF AN ADJUSTABLE FURNITURE SYSTEM, FURNITURE SYSTEM, ARRANGEMENT AND METHOD FOR CONFIGURING AN ELECTRONIC COMPONENT

(71) Applicant: LOGICDATA Electronic & Software Entwicklungs GmbH, Deutschlandsberg (AT)

(72) Inventor: Walter KOCH, Schwanberg (AT)

(21) Appl. No.: 16/256,979

(22) Filed: Jan. 24, 2019

(30) Foreign Application Priority Data
Jan. 25, 2018 (DE) 102018101690.5

(51) Int. Cl. H05K 1/02; G01R 1/067; A47B 9/04

(52) U.S. Cl. CPC H05K 1/029; G01R 1/0675; A47B 2200/0081; A47B 2200/0062; A47B 9/04

(57) ABSTRACT

An electronic component (1) of an adjustable furniture system comprises an opening (11) in a housing (10) and a plurality of contact areas (15). The component is arranged to enable establishing electrical contact to a programming interface (16) of a memory element (14) from outside through the opening (11) by means of a needle adapter (20) and to program the memory element (14).

The present disclosure relates to an electronic component, in particular for an adjustable furniture system, a furniture system equipped with such a component, and an arrangement and a method for configuring such an electronic component.

### BACKGROUND OF THE INVENTION

Due to the variety of constructions of electrically adjustable furniture, electronic components of such a furniture system, for example control units, are correspondingly diverse. In order to be able to use such a component in a flexible way and thus for as many different furniture systems as possible, the components are produced with a multitude of configuration options.

Furniture manufacturers usually purchase electronic components for their furniture systems from suppliers who at the present time program these during production and then deliver them to the furniture manufacturers. On the one hand, however, this means that the furniture manufacturer must commit himself to a specific configuration already when purchasing a component, and on the other hand that these configurations cannot be easily changed after production, for example to make adjustments or use them for another furniture system.

### SUMMARY OF THE INVENTION

The present disclosure provides an improved concept for the programming of electronic components for adjustable furniture systems so that the initial configuration as well as the adaptation of an existing configuration is possible even after production and, in particular, can easily be carried out by the furniture manufacturer himself.

Electronic components for adjustable furniture systems store data, such as configurations, typically in one or more non-volatile memory elements, such as a Flash or EEPROM module. The improved concept is based on the idea of developing a component that allows easier access to the programming interface of the memory element so that the configuration can be made and adapted even after the component has been manufactured. According to the improved concept, the component comprises a circuit board comprising a processor, a non-volatile memory element and a plurality of contact areas, at least one of which being electrically connected to a programming interface of the memory element. The circuit board is fixed in a housing that has at least one opening whose position corresponds to the contact areas. A component of this type is arranged such that the contact areas can be contacted by means of a needle adapter through the at least one opening of the housing in order to access the programming interface.

This access to the programming interface allows the programming of the component by means of a programming station after its complete production or even after delivery to the furniture manufacturer. The latter increases the production speed for the supplier and has the advantage for the furniture manufacturer that he can obtain the non-programmed components in large quantities and set them up flexibly according to his own requirements. The use of a needle adapter offers the possibility to automate the programming of the components in order to be able to handle high quantities. Compared to needle adapters, plug connectors commonly used have the disadvantage that they can only be used to a limited extent in automated production, as the automatic alignment and automatic insertion into the corresponding sockets are technically difficult to implement.

In one embodiment of the component, additionally at least one of the contact areas is electrically connected to a terminal for power supply to the memory element, and the component is set up such that the memory element is supplied with an electrical voltage via the needle adapter.

This means that the needle adapter alone is sufficient to supply the memory element with a voltage during the programming process, so that no separate power supply is required, for example from a power supply unit of the component.

In various embodiments, the memory element is either integrated in the processor or exists as a separate element on the circuit board. Optionally, the component may include a further non-volatile memory element, the programming interface of which is also electrically connected to at least one of the contact areas.

These different embodiments ensure that the component can be equipped with appropriate memory elements specific to the application so that sufficient memory capacity is available for the respective configuration of the component. More than one memory element may be required if, for example, the configuration is complex or the hardware architecture requires different parts of the configuration to be stored in different separate elements.

In this case, the electrical connection to both programming interfaces allows both memory elements to be programmed in parallel and independently of each other, as the needle adapter may also have several independent data lines.

Optionally, as with the first memory element, there may also exist an optional electrical connection from at least one of the contact areas to a terminal for a power supply of the memory element, so that the programming process can also be carried out for two memory elements without providing a power supply by, for example, a separate power supply unit.

The component is preferably set up in such a way that the programming interface allows direct access to a memory of the memory element, especially without using the processor.

Direct access to the programming interface has the advantage that, in contrast to typically used serial interfaces in which the memory elements are programmed via the processor of the component, this solution allows the memory modules to be addressed directly by a programming station, which results in significantly faster programming. The speed advantage here can be a factor of 10, since no translation from the serial interface to the programming interface is required.

The processor and the external memory elements of the component do not necessarily come from the same manufacturer. The programming interfaces are usually manufacturer-specific, so it may be necessary to have one programming interface each for the processor and the external memory devices. Therefore, the needle adapter having multiple data lines can support one or more separate programming interfaces.

In one embodiment of the component, the housing comprises a plurality of openings, such as holes, which correspond to a number of contact areas and whose positions correspond to the contact areas.

This allows automated contacting to be optimized to the extent that each needle of the needle adapter reaches a certain contact area in a straight line through its corresponding opening in the housing.

In general, the contact areas of the component are at a defined distance from the openings in the housing.

Typically, the contact areas are at a spatial distance from the housing feedthroughs, for example a few millimeters below the housing feedthrough. This allows easy contacting by means of a needle adapter through the openings of the housing.

In one embodiment, the component also includes an apparatus for mechanical support of the circuit board in the housing, especially in the region of the contact areas.

This apparatus, for example in the form of ribs or stiffeners, ensures that the contact force of the needles does not bend the circuit board, thus ensuring reliable and simultaneous contact of all needles. In addition, it is ensured that the circuit board is secured in the housing in non-displaceable fashion.

In a further embodiment of the component, the housing and the circuit board are cast with one another.

If the circuit board and housing are cast with one another, there is almost no distance between contact areas and openings, on the one hand, and on the other hand this further facilitates the contacting operation, especially in an automated process.

In general, the memory element is set up such that it stores a control program and parameters for adjusting the furniture system.

In addition to control software, the stored configuration includes furniture-specific parameters that describe the respective furniture system, e.g. the number of actuators used, control parameters such as for the adjustment speed, as well as parameters that activate or deactivate certain functionalities of the control of the furniture system, e.g. the activation of sensors for pinch detection.

In one embodiment, the opening in the housing is arranged in such a way that it is covered if the component is attached to a furniture system by means of a mounting apparatus.

According to such an attachment, the openings are protected against the penetration of dust or sharp objects, for example, and are also inaccessible to children, for instance.

As part of an adjustable furniture system, the component may be designed either as a control device, a hand switch or a power supply unit. It goes without saying that other possible uses of the component are not excluded.

The above mentioned object is also achieved by an electrically adjustable furniture system, which comprises an electric component for control according to one of the embodiments described above. Examples of such a furniture system include tables, reclining furniture and seating furniture.

Furthermore, a solution of the above mentioned object consists in an arrangement for programming an electronic component according to one of the embodiments described above. The arrangement comprises a device which is arranged to establish electrical contact with the contact areas of the component by means of a needle adapter through the opening in the housing. In addition, the arrangement comprises a data processing equipment which, while there is an electrical contact, is arranged to establish a data connection to the programming interface via the needle adapter and to program the memory element by means of the data processing equipment.

The data connection between the programming interface and the data processing equipment is usually a bidirectional bus link, such as an I2C bus or SPI bus, and can be used independently. This also allows parallel and simultaneous programming of two independent memory elements, another advantage that saves production time.

In one embodiment of the arrangement, the latter includes a power supply for the memory element.

The power supply of the memory elements to be programmed via the needle adapter significantly facilitates automation, as described in some embodiments of the component, since no additional separate power supply unit is required.

A further solution to the above object is provided by an operating method for configuring an electronic component according to one of the embodiments described above.

According to the method, an electronic component of an adjustable furniture system is configured. The method comprises passing a multi-pole needle adapter through an opening in a housing of the component, contacting a plurality of contact areas on a circuit board of the component electrically connected to a programming interface of a memory element on the circuit board by means of the needle adapter, establishing a data connection between a data processing equipment and the programming interface via the needle adapter, and programming the memory element by means of the data processing equipment.

One embodiment of the method comprises supplying the memory element with an electrical voltage via the needle adapter during programming.

Further embodiments of the method result from the described features of the component, which can be combined with each other in a suitable way.

### BRIEF DESCRIPTION OF THE DRAWINGS

Further advantageous embodiments are described in the claims as well as in the following description of exemplary embodiments on the basis of the attached Figures. The same reference signs are used in the Figures for elements with essentially the same function, but these elements do not have to be identical in all details.

In the Figures:

FIG. 1 is a schematic representation of an electronic component of an adjustable furniture system,

FIG. 2 shows an embodiment of an electronic component having a memory element integrated in a processor and an additional memory element,

FIG. 3 is a schematic representation of an arrangement for programming an electronic component of an adjustable furniture system, and

FIG. 4 shows the schematic structure of a height-adjustable table as an example of an electrically adjustable furniture system.

### DETAILED DESCRIPTION

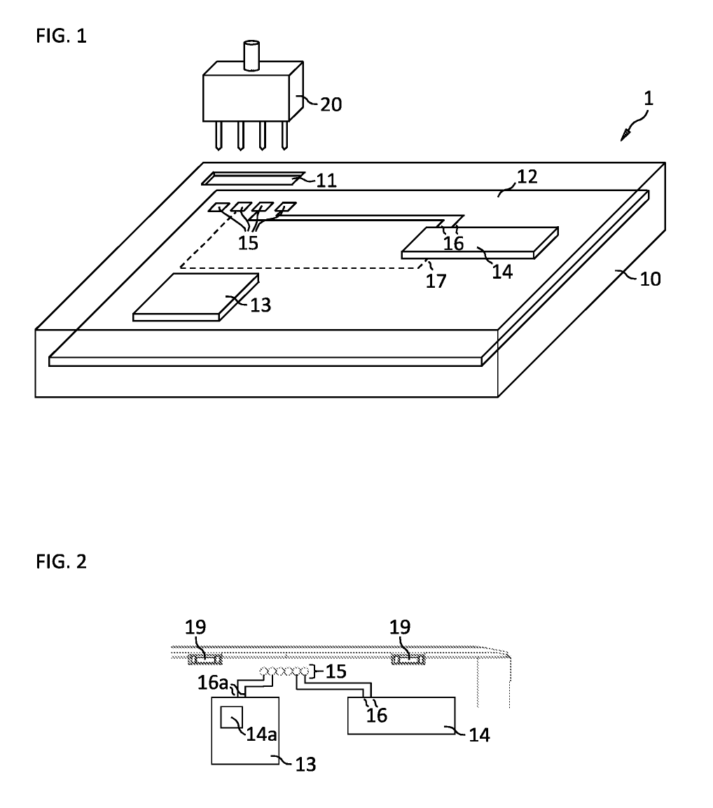

FIG. 1 is a schematic representation of an electronic component 1 of an adjustable furniture system. The component has a housing 10 with at least one opening 11 and a printed circuit board 12.

In various embodiments, the printed circuit board comprises a processor 13 and a memory element 14, preferably a non-volatile memory element, for example a flash or EEPROM module. In addition, there is a plurality of contact areas 15 on the circuit board, the position of which corresponds to the opening 11 in the housing 10. At least one of the contact areas is electrically connected to a programming interface 16 of the memory element 14. Programming interfaces are generally bidirectional bus connections, such as I2C or SPI-BUS, which are not designed for long data lines. Therefore, it makes sense to position the contact areas as close as possible to the memory element.

The contact areas 15 can be contacted by means of a needle adapter 20 through the opening 11 in the housing 10 in order to enable external access to the programming interface 16. In contrast to plug connections, contacting with a needle adapter is particularly suitable for automated production. Thus, plug connections have the disadvantage that automatic, angularly correct alignment and insertion into a corresponding socket are very difficult to implement.

In one embodiment, the component 1 is set up in such a way that the programming interface 16 allows direct access to a memory of the memory element 14, especially without using the processor 13, for example to load data into the memory. The programming interface 16 thus extended to the outside can therefore be addressed directly by a programming station using the needle adapter 20.

In contrast to a serial interface, in which the processor 13 of the component 1 translates serial instructions and processes transmitted data, a direct connection to the programming interface 16 of the memory element 14 enables a significantly faster loading of data, since a translation of instructions is not required and the processor 13 is not integrated.

In one embodiment, the memory element 14 of the component 1 is set up to store a control program as well as parameters for adjusting the furniture system.

Optionally, at least one of the contact areas 15 is additionally electrically connected to a power supply terminal 17 of the memory element, shown in FIG. 1 by a dashed connection. This allows the memory element 14 to be supplied with electrical power via the needle adapter 20 without the need for a separate power supply, e.g. from a power supply unit of the component.

For example, instead of a single, larger opening 11, the housing 10 of the component 1 has a plurality of openings corresponding to the number of contact areas 15, whose positions correspond to the contact areas 15. This allows the automatic angularly correct alignment to be optimized to ensure that the needles of the needle adapter 20 reach the contact areas 15 in a straight line. Furthermore, the correct alignment of the otherwise symmetrical needle adapter 20 can be ensured, for example, by different shapes of the individual openings 11.

In one embodiment, the contact areas 15 of the component 1 are located at a defined distance from the openings 11 in the housing 10. This enables uniform contacting of all contact areas 15 using the needle adapter 20.

In a further embodiment, the component 1 comprises an arrangement for the mechanical support of the circuit board 12 in the housing 10, especially in the area of the contact areas 15. This ensures that the circuit board 12 in the housing 10 neither moves nor bends due to the pressure of the needle adapter 20 during contacting.

In another embodiment of the component 1, the housing 10 and the circuit board 12 are cast with one another to ensure mechanical stability.

The component 1 is, for example, a control device, a hand switch or a power supply unit for the furniture system.

FIG. 2 shows a schematic representation of an embodiment of the component 1 in which, on the one hand, the circuit board 12 comprises apart from a memory element 14 an additional memory element 14a which is integrated in the processor 13. In this case, a majority of the contact areas 15 is connected both to the programming interface 16 of the memory element 14 and to the programming interface 16a of the memory element 14a. On the other hand, in addition to snap locks 19, the housing 10 contains a plurality of openings as described above, for example round holes, directly above the contact areas 15, which corresponds to the number of contact areas 15. For the sake of clarity, the openings are not shown in the drawing.

A second memory element may be required to provide a larger total memory, for example for furniture systems that require complex control. The bus connections of the programming interfaces 16 and 16a of the different memory elements 14 and 14a can be used independently of each other, so that parallel, simultaneous loading of the two independent memory elements 14 and 14a is possible.

The processor 13 and the memory element 14 may come from two different manufacturers. The fact that programming interfaces are often manufacturer-specific is circumvented in this case by the fact that a programming station can address several separate programming interfaces 16 and 16a in parallel using the needle adapter 20 which may have several independent data lines.

In one embodiment of the electronic component, the circuit board includes two separate non-volatile memory elements whose programming interfaces are electrically connected to some of the contact areas 15.

This embodiment is also used to expand the total memory in case, for example, the processor 13 does not include an integrated memory element 14a.

According to an embodiment described above, even in the case of multiple memory elements 14 and 14a, power supply terminals 17 can be electrically connected to at least one of the contact areas 15, so that the memory elements can be supplied with electrical power by the needle adapter during programming.

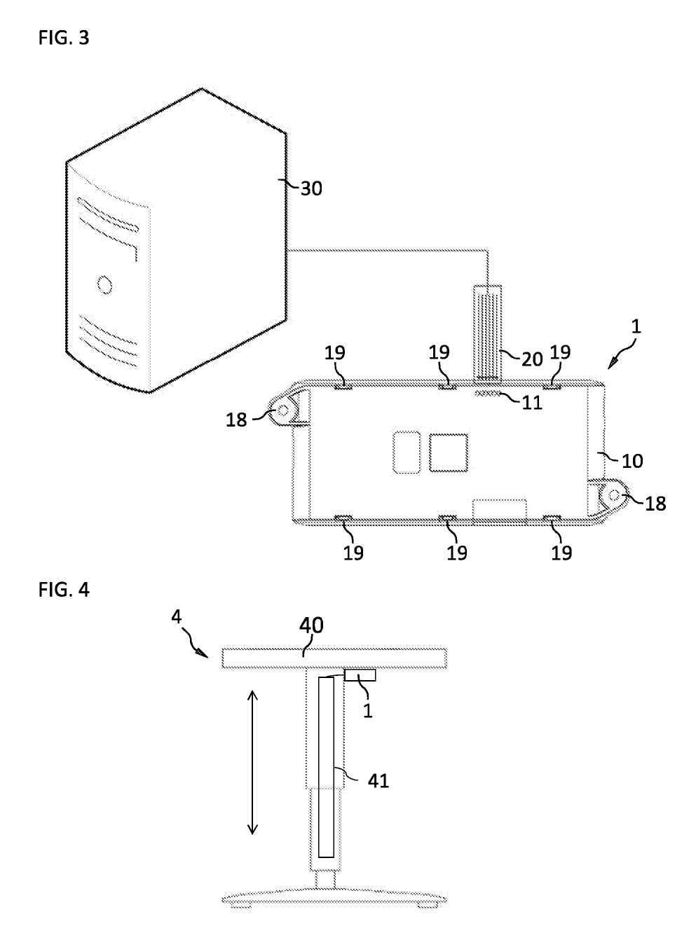

FIG. 3 shows a schematic illustration of an arrangement for programming an electronic component 1 to control an adjustable furniture system. The arrangement comprises a device arranged to make electrical contact with the contact areas 15 by means of a needle adapter 20 through the openings 11 in the housing 10 of the component 1. The arrangement further comprises a data processing equipment 30 arranged to establish a data connection to the programming interface 16 and to program the memory element 14 while the electrical contact is established.

In one embodiment, the arrangement further comprises a power supply for the memory element 14. Thus, the entire process of programming can be carried out by means of the needle adapter 20 without requiring a connection to a voltage supply via a separate power supply unit. This significantly increases productivity, especially when automating production.

The housing 10 of the component 1 includes, for example, a mounting device 18 which is set up in such a way that when the component 1 is mounted on a furniture system, the opening 11 in the housing 10 is covered by part of the furniture system. For this purpose, the mounting device 18 is attached on the same side as the opening 11. This protects the component 1 from the ingress of particles such as dirt or dust. This also prevents accidental entry into the openings, for example with pointed objects.

FIG. 4 shows a schematic structure of an electrically adjustable furniture system, which in this case is designed as a height-adjustable table 4. The table 4 has a table top 40 to which a component 1 is attached. The component 1, for example designed as a control unit, controls an adjustment drive 41 for height adjustment of table 4 or table top 40.

Other electrically adjustable furniture systems, which can be controlled by means of an electronic component 1, include beds, reclining furniture and seating furniture, for example.

It goes without saying that features shown in the description with regard to individual exemplary embodiments can be combined with each other in a suitable way.

1. An electronic component of an adjustable furniture system, the component comprising
a housing having at least one opening; and
a circuit board comprising a processor, a non-volatile memory element and a plurality of contact areas corresponding to the at least one opening, at least one of said contact areas being electrically connected to a programming interface of the memory element;
the component being arranged such that the contact areas can be contacted by means of a needle adapter through the at least one opening to access the programming interface.

2. The electronic component according to claim 1, in which additionally at least one of the contact areas is electrically connected to a terminal for a voltage supply of the memory element.

3. The electronic component according to claim 2, which is arranged such that the memory element is supplied with electrical voltage via the needle adapter.

4. The electronic component according to one of claims 1 to 3, in which the memory element is integrated in the processor.

5. The electronic component according to one of claims 1 to 3, in which the memory element is located outside the processor.

6. The electronic component according to one of claims 1 to 5, further comprising at least one further non-volatile memory element whose programming interface is electrically connected to the contact areas.

7. The electronic component according to one of claims 1 to 6, which is arranged such that the programming interface enables direct access to a memory of the memory element, in particular without using the processor.

8. The electronic component according to one of claims 1 to 7, wherein the housing comprises a plurality of openings corresponding to a number of the contact areas, whose positions correspond to the contact areas.

9. The electronic component according to one of claims 1 to 8, in which the contact areas are located at a defined distance from the openings in the housing.

10. The electronic component according to one of claims 1 to 9, further comprising an apparatus for mechanically supporting the circuit board in the housing, in particular in the region of the contact areas.

11. The electronic component according to one of claims 1 to 10, in which the housing and the circuit board are cast with one another.

12. The electronic component according to one of claims 1 to 11, in which the housing comprises a mounting apparatus which is located on the same side as the opening.

13. The electronic component according to one of claims 1 to 12, in which the memory element is arranged to store a control program as well as parameters for adjusting the furniture system.

14. The electronic component according to one of claims 1 to 13, in which the component is adapted to be one of the following components of the furniture system: a control device, a hand switch, a power supply unit.

15. An adjustable furniture system comprising an electronic component according to one of claims 1 to 14.

16. An arrangement for programming an electronic component according to one of claims 1 to 14, the arrangement comprising
a device arranged to establish electrical contact to the contact areas of the component through the opening in the housing by means of a needle adapter; and
a data processing equipment which is adapted to make a data connection to the programming interface via the needle adapter and to program the memory element while the electrical contact is established.

17. The arrangement according to claim 16, further comprising a power supply for the memory element of a component according to any of claims 2 to 14.

18. A method of configuring an electronic component of an adjustable furniture system, the method comprising:
passing a multi-pole needle adapter through an opening in a housing of the component;
contacting, by means of the needle adapter, a plurality of contact areas on a circuit board of the component which are electrically connected to a programming interface of a memory element on the circuit board; and
establishing a data connection between a data processing equipment and the programming interface via the needle adapter and programming the memory element by means of the data processing equipment.

19. The method according to claim 18, further comprising supplying the memory element with an electric voltage via the needle adapter during programming.
